(19) United States
(12) Patent Application Publication
(10) Pub. No.: US 2023/0180554 A1
(43) Pub. Date: Jun. 8, 2023

(54) LIGHT EMITTING DISPLAY DEVICE AND MANUFACTURING METHOD THEREOF

(71) Applicant: LG Display Co., Ltd., Seoul (KR)

(72) Inventors: Jong Sin PARK, Paju-si (KR); Hee Young CHAE, Paju-si (KR); Sung Won LEE, Paju-si (KR); Yi Yeon HWANG, Paju-si (KR)

(21) Appl. No.: 17/980,472

(22) Filed: Nov. 3, 2022

(30) Foreign Application Priority Data
Dec. 7, 2021 (KR) 10-2021-0173752

(51) Int. Cl. H01L 27/32; H01L 51/56

(52) U.S. Cl. CPC H01L 27/3276; H01L 51/56; H01L 2227/323

(57) ABSTRACT

The present disclosure provides a light emitting display device including a low-level voltage power line configured to transmit a low-level voltage, a data line configured to transmit a data voltage, a gate line configured to transmit a gate signal, and a subpixel connected to the low-level voltage power line, the data line and the gate line. The subpixel includes a capacitor overlapping with the low-level voltage power line.

### CROSS-REFERENCE TO RELATED APPLICATION(S)

This application claims the benefit of Korean Patent Application No. 10-2021-0173752 filed on Dec. 7, 2021, which is hereby incorporated by reference as if fully set forth herein.

### BACKGROUND

### Technical Field

The present disclosure relates to a light emitting display device and a manufacturing method thereof.

### Description of the Related Art

In accordance with development of information technology, the market for display devices as a medium interconnecting users and information is expanding. As such, use of display devices such as a light emitting display (LED) device, a quantum dot display (QDD) device, a liquid crystal display (LCD) device and the like is increasing.

The above-mentioned display devices include a display panel including subpixels, a driver configured to output a drive signal for driving the display panel, and a power supply configured to generate electric power to be supplied to the display panel or the driver.

When drive signals, for example, scan signals and data signals, are supplied to subpixels formed at a display panel in a display device as mentioned above, selected ones of the subpixels transmit light or directly emit light and, as such, the display device may display an image.

### BRIEF SUMMARY

The disclosure provides devices that have increased brightness and/or increased image quality.

The present disclosure is directed to a light emitting display device and a manufacturing method thereof that, among others, substantially obviate one or more problems due to limitations and disadvantages of the related art.

The present disclosure provides a light emitting display device and a manufacturing method thereof which are capable of achieving an increase in aperture ratio by increasing an area occupied by an organic light emitting diode while minimizing an area required for implementation of a circuit. In a first aspect and a second aspect of the present disclosure the capacitor overlaps with the low-level voltage power line to increase an area occupied by an organic light emitting diode while minimizing an area required for implementation of the circuit, thereby increasing the aperture ratio. Overlapping of a driving transistor with the low level voltage power line may further help to achieve the above object of the present disclosure.

The present disclosure provides a light emitting display device and a manufacturing method thereof which are capable of stabilizing power of a low-level voltage, thereby achieving an enhancement in display quality. In a second aspect of the present disclosure disposition of the low-level voltage power line in each subpixel stabilizes power of the low voltage level and reduces line resistance, thereby achieving an enhancement in display quality of the resultant display panel.

Further, by providing a light emitting display device according to the second aspect, in which the first group and the second group have vertically inverted relations, more efficient space utilization may be achieved, as will become clear form the detailed description.

Additional advantages, technical benefits, and features of the disclosure will be set forth in part in the description which follows and in part will become apparent to those having ordinary skill in the art upon examination of the following or may be learned from practice of the disclosure. The technical benefits and other advantages of the disclosure may be realized and attained by the structure particularly pointed out in the written description and embodiments hereof as well as the appended drawings.

Disclosed herein is a light emitting display device which includes a low-level voltage power line configured to transmit a low-level voltage, a data line configured to transmit a data voltage, a gate line configured to transmit a gate signal, and a subpixel connected to the low-level voltage power line, the data line and the gate line, the subpixel including a capacitor overlapping with the low-level voltage power line. The low-level voltage power line may alternatively be referred to herein as a second power line.

The subpixel may further include a driving transistor having a gate electrode connected to a first electrode of the capacitor, and the driving transistor may overlap with the low-level voltage power line.

The first electrode and a second electrode of the capacitor may overlap with the low-level voltage power line. The gate electrode and a channel region of the driving transistor may overlap with the low-level voltage power line.

The subpixel may include the low-level voltage power line disposed on a subpixel, a buffer layer disposed on the low-level voltage power line, a semiconductor layer disposed on a buffer layer, a gate insulating layer disposed on the semiconductor layer, a gate metal layer disposed on the gate insulating layer, an interlayer insulating layer disposed on the gate metal layer, and a pixel electrode layer disposed on the interlayer insulating layer. A metal layer may be provided between the semiconductor layer and the gate metal layer, to contact the semiconductor layer and the gate metal layer.

The subpixel may include the low-level voltage power line disposed on a subpixel, a buffer layer disposed on the low-level voltage power line, a semiconductor layer disposed on a buffer layer, a metal layer (e.g., first metal layer) disposed on the semiconductor layer, a gate metal layer disposed on the first metal layer, and a gate insulating layer disposed between the semiconductor layer and the gate metal layer. The first metal layer may be in contact with the semiconductor layer and with the gate metal layer.

The semiconductor layer may be selected as an oxide semiconductor including a semiconductor region and a metallized region. The semiconductor layer may further include a metal layer disposed in the metallized region.

The pixel electrode layer may contact a portion of the metal layer via a contact hole provided at the interlayer insulating layer and the gate insulating layer, thereby being electrically connected to the metallized region.

The pixel electrode layer may be directly connected to the metallized region via a contact hole provided at the interlayer insulating layer and the gate insulating layer.

Also disclosed herein is a light emitting display device including a display panel including subpixels each connected to a low-level voltage power line, a data line and a gate line, each of the subpixels including a capacitor overlapping with the low-level voltage power line, and a driver configured to drive the display panel, wherein the subpixels include a first group and a second group each including two subpixels laterally symmetrical with each other, and the first group and the second group have vertically inverted relations, respectively.

A first electrode and a second electrode of the capacitor may overlap with the low-level voltage power line. A gate electrode and a channel region of the driving transistor may overlap with the low-level voltage power line.

Also disclosed herein is a manufacturing method of a light emitting display device including forming, on a substrate, a subpixel connected to a low-level voltage power line, a data line and a gate line while including a capacitor overlapping with the low-level voltage power line, and encapsulating the subpixel formed on the substrate, wherein the capacitor includes a first electrode disposed on a buffer layer covering the low-level voltage power line, and a second electrode disposed on a gate insulating layer covering the one-end electrode, and wherein the first electrode of the capacitor includes a metallized oxide semiconductor layer.

In accordance with the examples of the present disclosure, there is an effect of achieving an increase in aperture ratio by increasing an area occupied by an organic light emitting diode while minimizing an area required for implementation of a circuit through formation of a capacitor and a driving transistor. In addition, there is an effect of stabilizing power of a low voltage level and reducing a line resistance through disposition of a low-level voltage power line in each area in which a subpixel is disposed, thereby achieving an enhancement in display quality of the resultant display panel. Furthermore, there is an effect of compensating a driving transistor without implementation of a separate compensation circuit in a data driver, etc., thereby achieving an enhancement in display quality of the resultant display panel and an increase in lifespan of the display panel.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate example(s) of the disclosure and along with the description serve to explain the principle of the disclosure. In the drawings:

FIG. 1 is a block diagram schematically showing a light emitting display device;

FIG. 2 is a diagram schematically showing a subpixel shown in FIG. 1;

FIGS. 3A and 3B are views showing disposition examples of a gate-in-panel type gate driver;

FIGS. 4 and 5 are views illustrating configurations of elements associated with the gate-in-panel type gate driver;

FIG. 6 is a circuit diagram of a circuit configuration of a subpixel according to a first example of the first aspect;

FIG. 7 is an illustrative layout view of the subpixel according to the first example of the first aspect;

FIG. 8 is an illustrative cross-sectional view taken along line X1-X2 in FIG. 7;

FIG. 9 is a circuit diagram of a circuit configuration of a subpixel according to a second example of the first aspect;

FIG. 10 is an illustrative layout view of the subpixel according to the second example of the first aspect;

FIGS. 11 to 13 are diagrams explaining an advantage of the subpixel according to the second example of the first aspect;

FIG. 14 is an illustrative layout view of subpixels according to a third example of the first aspect;

FIG. 15 is an illustrative cross-sectional view taken along line A1-A2 in FIG. 14;

FIG. 16 is an illustrative cross-sectional view taken along line B1-B2 in FIG. 14;

FIGS. 17 and 18 are illustrative cross-sectional views taken along line B1-B2 in FIG. 14, showing variants of the third example of the first aspect;

FIG. 19 is an illustrative layout view of subpixels according to a fourth example of the first aspect;

FIG. 20 is an illustrative cross-sectional view taken along line C1-C2 in FIG. 19;

FIG. 21 is an illustrative cross-sectional view taken along line D1-D2 in FIG. 19;

FIG. 22 is an illustrative cross-sectional view taken along line D1-D2 in FIG. 19, showing a variant of the fourth example of the first aspect; and

FIG. 23 is a circuit diagram of a circuit configuration of a subpixel according to a fifth example of the first or second aspects.

### DETAILED DESCRIPTION

A display device according to an example of the present disclosure may be implemented as a television, an image player, a personal computer (PC), a home theater, an automobile electric device, a smartphone, etc., without being limited thereto. The display device may be implemented as a light emitting display (LED) device, a quantum dot display (QDD) device, a liquid crystal display (LCD) device, etc. However, the following description will be given in conjunction with, for example, a light emitting display device configured to directly emit light based on an inorganic light emitting diode or an organic light emitting diode, for convenience of description.

Although a subpixel, which will be described hereinafter, will be described in conjunction with an example in which the subpixel includes an n-type thin film transistor, the subpixel may be implemented to include a p-type thin film transistor or a thin film transistor having a type in which both the n type and the p type are present. The thin film transistor may be a triple-electrode element including a gate, a source and a drain. The source is an electrode configured to supply a carrier to the transistor. The carrier in the thin film transistor first flows from the source. The drain is an electrode from which the carrier is discharged from the thin film transistor to an exterior of the thin film transistor. That is, the carrier in the thin film transistor flows from the source to the drain.

In the case of a p-type thin film transistor, a source voltage has a higher level than a drain voltage such that a hole may flow from a source to a drain because the hole is a carrier. In the p-type thin film transistor, current flows from the source to the drain because the hole flows from the source to the drain. Conversely, in an n-type thin film transistor, a source voltage has a lower level than a drain voltage such that an electron may flow from a source to a drain because the electron is a carrier. In the n-type thin film transistor, current flows from the drain to the source because the electron flows from the source to the drain. In a thin film transistor, however, a source and a drain may be interchanged in accordance with voltages applied thereto. Taking into consideration such conditions, one of the source and the drain will be referred to as a “first electrode,” and the other of the source and the drain will be referred to as a “second electrode.”

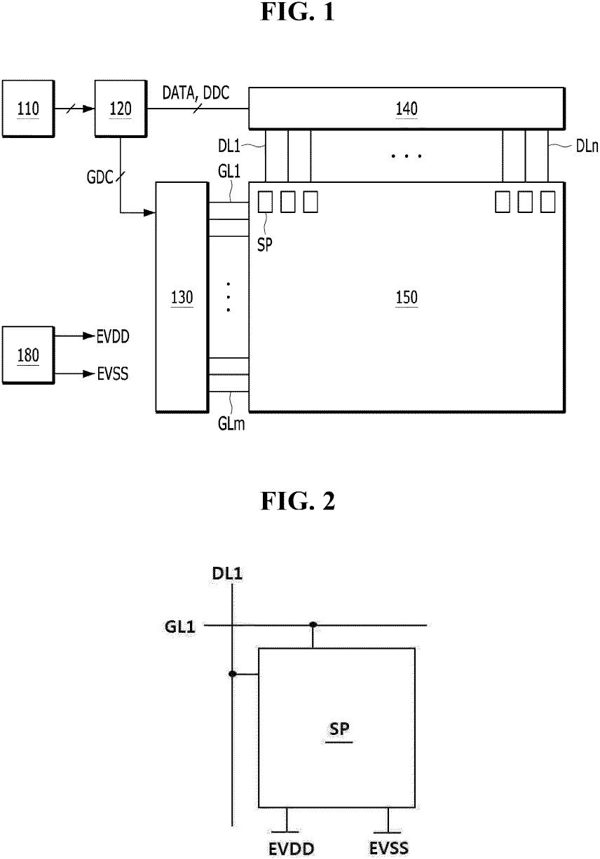

FIG. 1 is a block diagram schematically showing a light emitting display device. FIG. 2 is a diagram schematically showing a subpixel shown in FIG. 1.

As shown in FIGS. 1 and 2, the light emitting display device may include an image supplier 110, a timing controller 120, a gate driver 130, a data driver 140, a display panel 150, a power supply 180, etc.

The image supplier 110 (a set or a host system) may output various driving signals together with an image data signal supplied from an exterior thereof or an image data signal stored in an internal memory thereof. The image supplier 110 may supply a data signal and various driving signals to the timing controller 120.

The timing controller 120 may output a gate timing control signal GDC for control of an operation timing of the gate driver 130, a data timing control signal DDC for control of an operation timing of the data driver 140, various synchronization signals (a vertical synchronization signal Vsync and a horizontal synchronization signal Hsync), etc. The timing controller 120 may supply, to the data driver 140, a data signal DATA supplied from the image supplier 110 together with the data timing signal DDC. The timing controller 120 may take the form of an integrated circuit (IC) and, as such, may be mounted on a printed circuit board, without being limited thereto.

The gate driver 130 may output a gate signal (or a scan signal) in response to the gate timing control signal GDC supplied from the timing controller 120. The gate driver 130 may supply a gate signal to the subpixels included in the display panel 150 through gate lines GL1 to GLm. The gate driver 130 may take the form of an IC or may be directly formed on the display panel 150 in a gate-in-panel manner, without being limited thereto.

The data driver 140 may sample and latch a data signal DATA in response to the data timing control signal DDC supplied from the timing controller 120, may convert the resultant data signal, which has a digital form, into a data voltage having an analog form, based on a gamma reference voltage, and may output the data voltage. The data driver 140 may supply the data voltage to the subpixels included in the display panel 150 through data lines DL1 to DLn. The data driver 140 may take the form of an IC and, as such, may be mounted on the display panel 150 or may be mounted on a printed circuit board, without being limited thereto.

The power supply 180 may generate first power of a high-level voltage and second power of a low-level voltage based on an external input voltage supplied from an exterior thereof, and may output the first power and the second power through a first power line (high-level voltage power line) EVDD and a second power line (low-level voltage power line) EVSS. The power supply 180 may generate and output not only the first power and the second power, but also a voltage (for example, a gate voltage including a gate-high voltage and a gate-low voltage) required for driving of the gate driver 130, a voltage (a drain voltage and a drain voltage including a half drain voltage) required for driving of the data driver 140, etc.

The display panel 150 may display an image, corresponding to the driving signal including the gate signal and the data voltage, the first power, the second power, etc. The subpixels of the display panel 150 may directly emit light. The display panel 150 may be fabricated based on a substrate having stiffness or ductility, such as glass, silicon, polyimide or the like. The subpixels, which emit light, may be constituted by red, green and blue subpixels or red, green, blue and white subpixels.

For example, one subpixel SP may include a pixel circuit connected to a first data line DL1, a first gate line GL1, a first power line EVDD and a second power line EVSS while including a switching transistor, a driving transistor, a capacitor, an organic light emitting diode, etc. The subpixel SP, which is used in the light emitting display device, has a complex circuit configuration because the subpixel SP directly emits light. Furthermore, a compensation circuit configured to compensate for degradation of not only the organic light emitting diode, which emits light, but also the driving transistor configured to supply, to the organic light emitting diode, driving current required for driving of the organic light emitting diode, etc., is also diverse. For convenience of illustration, however, the subpixel SP is simply shown in the form of a block.

Meanwhile, in the above description, the timing controller 120, the gate driver 130, the data driver 140, etc., have been described as having individual configurations, respectively. However, one or more of the timing controller 120, the gate driver 130 and the data driver 140 may be integrated into one IC in accordance with an implementation type of the light emitting display device.

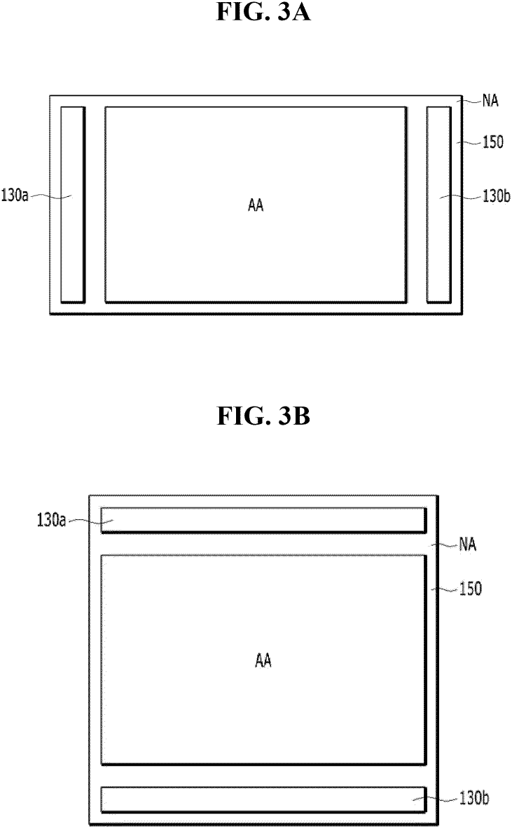

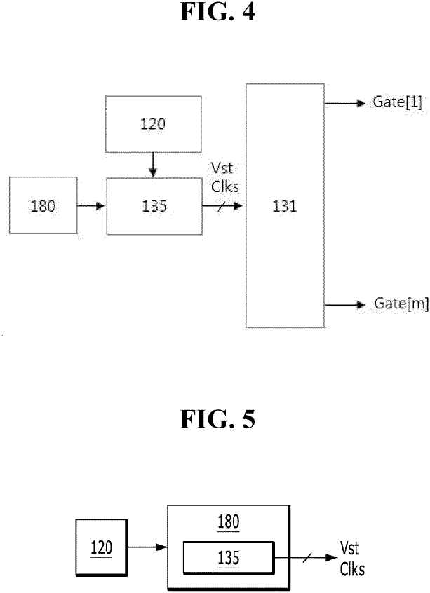

FIGS. 3A and 3B are views showing disposition examples of a gate-in-panel type gate driver. FIGS. 4 and 5 are views illustrating configurations of elements associated with the gate-in-panel type gate driver.

As shown in FIGS. 3A and 3B, gate-in-panel type gate drivers 130a and 130b are disposed in a non-display area NA of a display panel 150. The gate drivers 130a and 130b may be disposed in left and right non-display areas NA of the display panel 150, as shown in FIG. 3A, or may be disposed in upper and lower non-display areas NA of the display panel 150, as shown in FIG. 3B.

Although the gate drivers 130a and 130b have been shown and described as being disposed in the non-display areas NA disposed at left and right sides or upper and lower sides of a display area AA, only one gate driver may be disposed at the left, right, upper or lower side.

As shown in FIG. 4, the gate-in-panel type gate driver may include a shift register 131 and a level shifter 135. The level shifter 135 may generate clock signals Clks, a start signal Vst, etc., based on signals and voltages output from a timing controller 120 and a power supply 180. The clock signals Clks may be generated under the condition that the clock signals Clks have K different phases (K being an integer of 2 or greater), such as 2-phase, 4-phase, 8-phase, etc.

The shift register 131 may operate based on the signals Clks, Vst, etc., output from the level shifter 135, and may output gate signals Gate[1] to Gate[m] capable of turning on or off transistors formed at a display panel. The shift register 131 may be formed on the display panel in a gate-in-panel manner in the form of a thin film. Accordingly, “130a” and “130b” indicated in FIGS. 3A and 3B may correspond to the shift register 131.

As shown in FIGS. 4 and 5, the level shifter 135 may be independently formed in the form of an IC or may be internally included in the power supply 180, differently from the shift register 131. However, this configuration is only illustrative, and the examples of the present disclosure are not limited thereto.

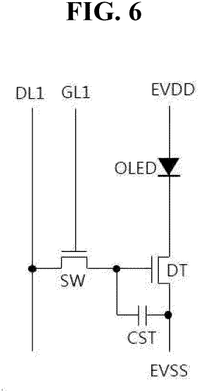

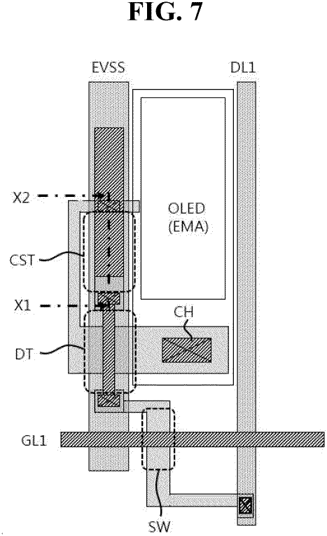

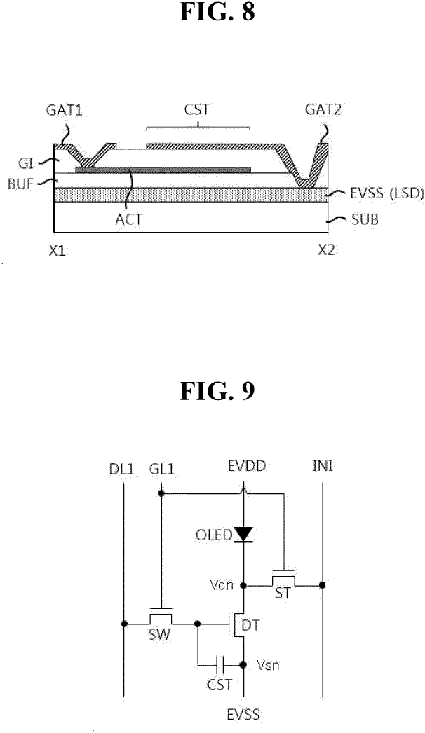

FIG. 6 is a circuit diagram of a circuit configuration of a subpixel according to a first example of the present disclosure. FIG. 7 is an illustrative layout view of the subpixel according to the first example of the present disclosure. FIG. 8 is an illustrative cross-sectional view taken along line X1-X2 in FIG. 7.

As shown in FIG. 6, in accordance with the first example of the present disclosure, the subpixel may include a switching transistor SW, a driving transistor DT, a capacitor CST, and an organic light emitting diode OLED.

The switching transistor SW may be connected, at a gate electrode thereof, to a first gate line GL1 while being connected, at a first electrode thereof, to a first data line DL1 and connected, at a second electrode thereof, to a gate electrode of the driving transistor DT and a one-end electrode (first electrode) of the capacitor CST. The switching transistor SW may function to transmit, to the one-end electrode of the capacitor CST, a data voltage applied thereto through the first data line DL1.

The driving transistor DT may be connected, at the gate electrode thereof, to the second electrode of the switching transistor SW and the one-end electrode of the capacitor CST while being connected, at a first electrode thereof, to a cathode of the organic light emitting diode OLED and connected, at a second electrode thereof, to an other-end electrode (second electrode) of the capacitor CST and a second power line EVSS. The driving transistor DT may function to generate driving current, corresponding to a data voltage stored in the capacitor CST.

The capacitor CST may be connected, at the one-end electrode thereof, to the second electrode of the switching transistor SW and the gate electrode of the driving transistor DT while being connected, at the other-end electrode thereof, to the second electrode of the driving transistor DT and the second power line EVSS. The capacitor CST may function to store a data voltage for driving of the driving transistor DT.

The organic light emitting diode OLED may be connected, at the anode thereof, to the first power line EVDD while being connected, at the cathode thereof, to the first electrode of the driving transistor DT. The organic light emitting diode OLED may function to emit light, corresponding to operation of the driving transistor DT.

As shown in FIG. 7, in accordance with the first example of the present disclosure, the capacitor CST may overlap with the second power line EVSS. In addition, the driving transistor DT may overlap with the second power line EVSS. The overlapping is observed in plan view, e.g., in the view shown in FIG. 7. The plan view is defined herein as a view taken in a direction perpendicular to the plane of the display device, e.g., perpendicular to the plane of the substrate on which the subpixel(s) is/are disposed. Each electrode of the capacitor CST may overlap with the second power line EVSS. For example, the capacitor CST may overlap with the second power line EVSS at the one-end electrode thereof. In one embodiment, it may also overlap at the other-end electrode thereof. Thus if just one electrode of the capacitor overlaps the low power line EVSS, then the capacitor is considered to be overlapping the EVSS. The driving transistor DT may overlap with the second power line EVSS at the gate electrode thereof and in a channel region thereof. To this end, the capacitor CST and the driving transistor DT may be disposed along the second power line EVSS. For example, the capacitor CST and the driving transistor DT may be disposed along a first direction (the up-down direction in FIG. 7), which is parallel to the direction in which the second power line EVSS extends in the plan view. The first direction is parallel to the plane of the display device. As the reader will understand, the channel region of the transistor refers to the region of the transistor which extends between the drain and the source of the transistor.

The organic light emitting diode OLED may be disposed between the second power line EVSS, which is disposed at a first side of the OLED (the left side in FIG. 7), and the first data line DL1, which is disposed at a second side of the LED (the right side in FIG. 7). The OLED may be elongate in plan view, and may extend in the first direction. The cathode of the organic light emitting diode OLED may be electrically connected to the first electrode of the driving transistor DT via a contact hole CH.

The switching transistor SW may be disposed at a lower end of the driving transistor DT. The first gate line GL1 may be disposed to extend in a second direction (the left-right direction in FIG. 7) in an area in which the switching transistor SW is disposed. The second direction is perpendicular to the first direction, and is parallel to the plane of the display device.

The second power line EVSS may have a greater line width than the first data line DL1 or the first gate line GL1, in order to achieve a reduction in line resistance thereof and overlapping disposition thereof with the capacitor CST and the driving transistor DT. The second power line EVSS and the first data line DL1 may be disposed at the same layer, and the first gate line GL1 may be disposed on an insulating layer covering the second power line EVSS and the first data line DL1. This can be seen by referring to the following description given with reference to FIG. 8.

In addition, the contact hole CH may be disposed between an emission area EMA of the organic light emitting diode OLED and the first gate line GL1, whereas the capacitor CST may be disposed adj acent to the emission area EMA of the organic light emitting diode OLED, and the driving transistor DT may be disposed adjacent to the contact hole CH.

As shown in FIGS. 7 and 8, the second power line EVSS may be disposed on a substrate SUB. The second power line EVSS may also function as a light shielding layer LSD configured to shield external light incident upon a channel region CHA of the driving transistor DT. To this end, as a material of the second power line EVSS, a material exhibiting an excellent optical blocking ratio may be selected. A buffer layer BUF may be formed on the second power line EVSS, and may expose a portion of the second power line EVSS.

A semiconductor layer ACT may be formed on the buffer layer BUF. As a material of the semiconductor layer ACT, an oxide semiconductor, for example, indium-gallium-zinc oxide (IGZO), may be selected. In the semiconductor layer ACT, a portion thereof constituting the capacitor CST may also be metallized in order to function as an electrode. The semiconductor layer ACT may be partially metallized by a plasma process, a dry etching process, a substance (for example, hydrogen) doping process, or the like, and one of the processes may be selected as an easy process in accordance with a manufacturing method.

A gate insulating layer GI may be formed on the buffer layer BUF, and may expose a portion of the semiconductor layer ACT. Gate metal layers GAT1 and GAT2 may be formed on the gate insulating layer GI. The first gate metal layer GAT1 may be electrically connected to the portion of the semiconductor layer ACT exposed through the gate insulating layer GI. The second gate metal layer GAT2 may be electrically connected to the portion of the second power line EVSS exposed through the gate insulating layer GI and the buffer layer BUF.

The semiconductor layer ACT shown in FIG. 8 may be metallized to constitute the one-end electrode of the capacitor CST. The semiconductor layer ACT, metallized to constitute the one-end electrode of the capacitor CST, may be electrically connected to the second electrode of the switching transistor SW by the first gate metal layer GAT1. The second gate metal layer GAT2 electrically connected to the second power line EVSS may constitute the other-end electrode of the capacitor CST.

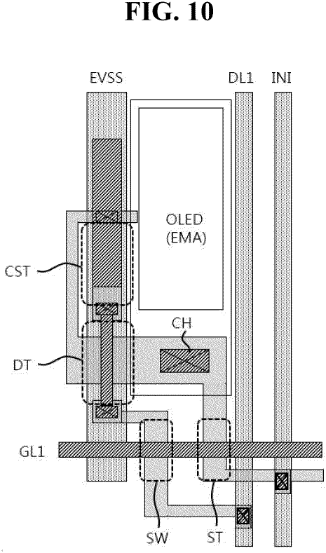

FIG. 9 is a circuit diagram of a circuit configuration of a subpixel according to a second example of the present disclosure. FIG. 10 is an illustrative layout view of the subpixel according to the second example of the present disclosure. FIGS. 11 to 13 are diagrams explaining an advantage of the subpixel according to the second example of the present disclosure.

As shown in FIG. 9, in accordance with the second example of the present disclosure, the subpixel may include a switching transistor SW, a driving transistor DT, a compensation transistor ST, a capacitor CST, and an organic light emitting diode OLED.

The switching transistor SW may be connected, at a gate electrode thereof, to a first gate line GL1 while being connected, at a first electrode thereof, to a first data line DL1 and connected, at a second electrode thereof, to a gate electrode of the driving transistor DT and a one-end electrode of the capacitor CST. The switching transistor SW may function to transmit, to the one-end electrode of the capacitor CST, a data voltage applied thereto through the first data line DL1.

The driving transistor DT may be connected, at the gate electrode thereof, to the second electrode of the switching transistor SW and the one-end electrode of the capacitor CST while being connected, at a first electrode thereof, to a cathode of the organic light emitting diode OLED and connected, at a second electrode thereof, to an other-end electrode of the capacitor CST and a second power line EVSS. The driving transistor DT may function to generate driving current, corresponding to a data voltage stored in the capacitor CST.

The capacitor CST may be connected, at the one-end electrode thereof, to the second electrode of the switching transistor SW and the gate electrode of the driving transistor DT while being connected, at the other-end electrode thereof, to the second electrode of the driving transistor DT and the second power line EVSS. The capacitor CST may function to store a data voltage for driving of the driving transistor DT.

The compensation transistor ST may be connected, at a gate electrode thereof, to the first gate line GL1 while being connected, at a first electrode thereof, to the cathode of the organic light emitting diode OLED and the first electrode of the driving transistor DT and connected, at a second electrode thereof, to a compensation line INI. The compensation transistor ST may function to apply a voltage for compensation of a threshold voltage of the driving transistor DT or a voltage for initialization.

The organic light emitting diode OLED may be connected, at the anode thereof, to the first power line EVDD while being connected, at the cathode thereof, to the first electrode of the driving transistor DT and the first electrode of the compensation transistor ST. The organic light emitting diode OLED may function to emit light, corresponding to operation of the driving transistor DT.

As shown in FIG. 10, in accordance with the second example of the present disclosure, the capacitor CST and the driving transistor DT may be disposed to extend in a first direction (a vertical direction) of the second power line EVSS, identically to the first example.

The compensation transistor ST, which is further included in the second example, may be disposed between the switching transistor SW and the first data line DL1. In addition, the compensation line INI connected to the compensation transistor ST may be disposed adjacent to the first data line DL1. The cross-sectional structure of the capacitor CST is identical to that of the first example and, as such, for a description thereof, refer to the description given with reference to FIG. 8.

Hereinafter, a sensingless compensation method of the subpixel according to the second example of the present disclosure will be described.

As shown in FIG. 11, during an initialization period, the compensation line INI may be initialized, together with a first node Vdn of the driving transistor DT. For this initialization, a first data voltage capable of turning on the driving transistor DT may be applied to the first data line DL1, and an initialization voltage may be applied to the compensation line INI.

During the initialization period, a low-level voltage may be applied to the first power line EVDD, and a high-level voltage may be applied to the second power line EVSS. As a result, the organic light emitting diode OLED may be maintained in a turned-off state. The initialization voltage may be applied in accordance with a turning-on operation of a switch VSW disposed between the compensation line INI and a reference voltage source VRF, without being limited thereto.

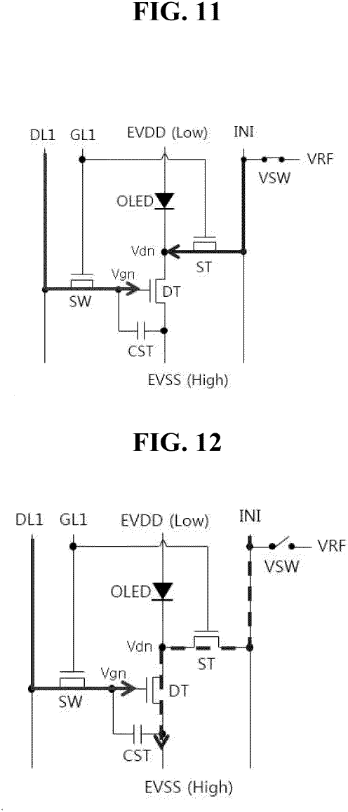

As shown in FIG. 12, during a threshold voltage sensing period, the switch VSW disposed between the compensation line INI and the reference voltage source VRF may be turned off. As a result, a threshold voltage of the driving transistor DT may be sensed in accordance with discharge of the initialization voltage and a source following operation in the driving transistor DT.

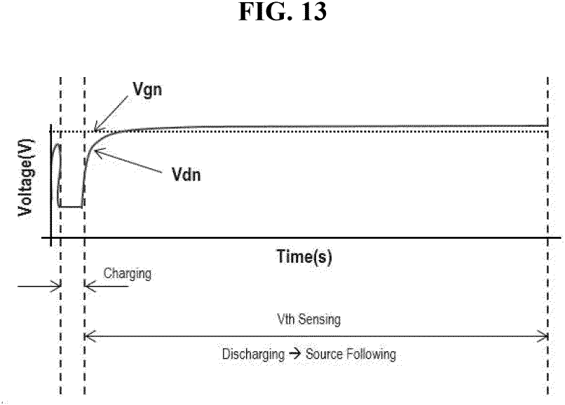

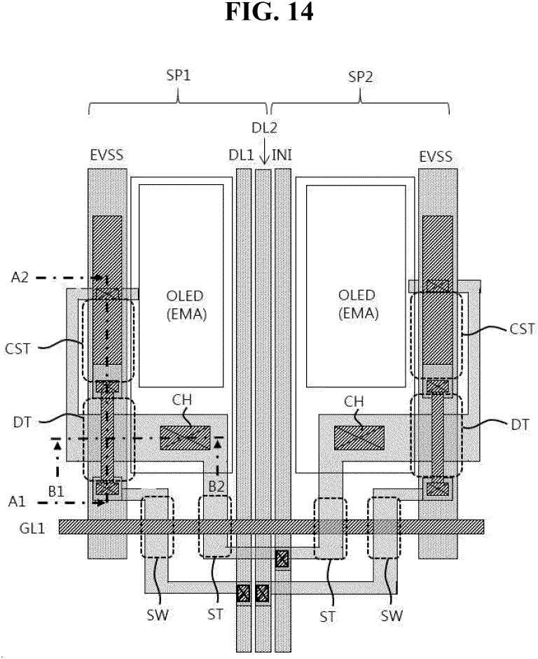

As shown in FIG. 13, referring to variations in a voltage Vgn applied to the gate node of the driving transistor DT and a voltage Vdn applied to the drain node of the driving transistor DT, it can be seen that threshold voltage sensing is possible in accordance with the source following operation of the driving transistor DT. In some embodiments, in the subpixel according to the second example of the present disclosure, a threshold voltage sensing operation of the driving transistor DT may be achieved through charge and discharge of the initialization voltage. As such, in the second example of the present disclosure, it may be possible to not only achieve an increase in aperture ratio, but also to achieve sensingless compensation calibration and compensation of the driving transistor DT.

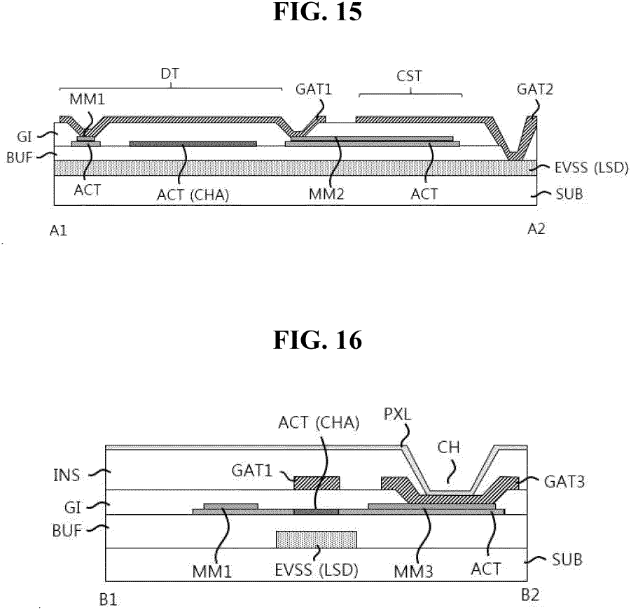

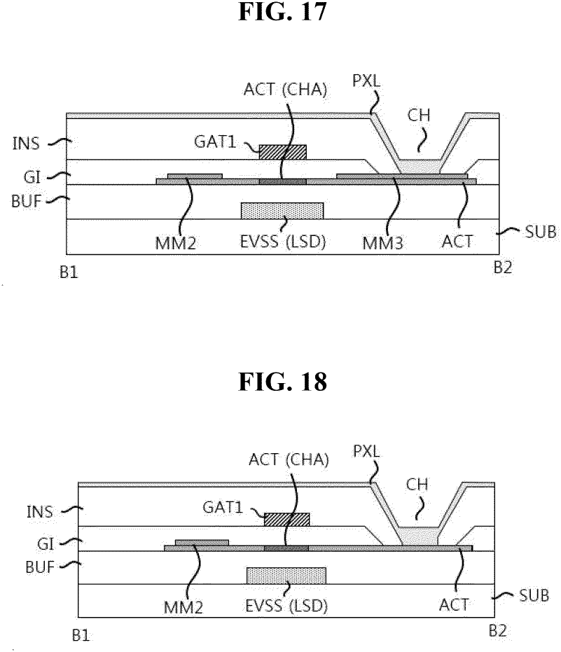

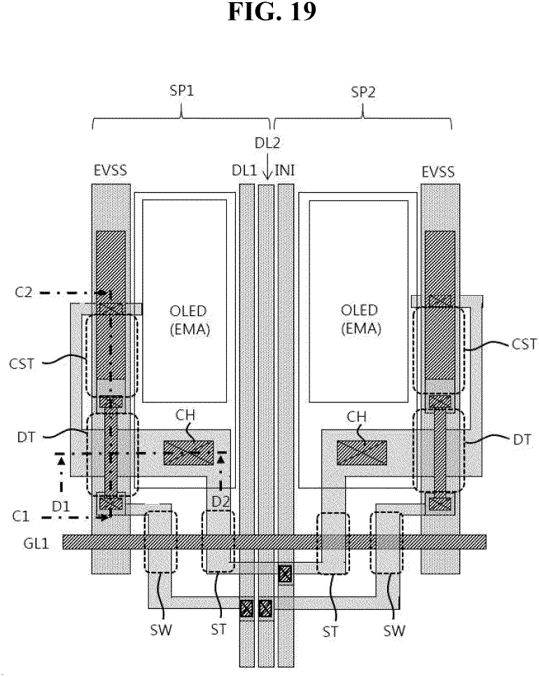

FIG. 14 is an illustrative layout view of subpixels according to a third example of the present disclosure. FIG. 15 is an illustrative cross-sectional view taken along line A1-A2 in FIG. 14. FIG. 16 is an illustrative cross-sectional view taken along line B1-B2 in FIG. 14. FIGS. 17 and 18 are illustrative cross-sectional views taken along line B1-B2 in FIG. 14, showing variants of the third example of the present disclosure.

As shown in FIG. 14, in accordance with the third example of the present disclosure, a first subpixel SP1 and a second subpixel SP2 may each include a switching transistor SW, a driving transistor DT, a compensation transistor ST, a capacitor CST, and an organic light emitting diode OLED. In addition, the capacitor CST and the driving transistor DT may be disposed to extend in a first direction (a vertical direction) of a second power line EVSS in order to overlap with the second power line EVSS.

The first subpixel SP1 and the second subpixel SP2 may share a compensation line INI. The first subpixel SP1 may be disposed between a one-side (left) second power line EVSS and a first data line DL1, and the second subpixel SP2 may be disposed between a second data line DL2 and an other-side (right) second power line EVSS.

The first subpixel SP1 and the second subpixel SP2 may be disposed to be laterally symmetrical with each other with reference to the first data line DL1, the second data line DL2 and the compensation line INI disposed therebetween. Of course, contact structures disposed below a first gate line GL1 may be laterally symmetrical with each other or may be laterally asymmetrical with each other in accordance with a disposition relationship of the first data line DL1, the second data line DL2 and the compensation line INI. For example, the disposition order of the first data line DL1, the second data line DL2 and the compensation line INI may be changed into the disposition order of the first data line DL1, the compensation line INI and the second data line DL2. In this case, the first subpixel SP1 and the second subpixel SP2 may be completely laterally symmetrical with each other.

The second power lines EVSS, the first data line DL1, the second data line DL2 and the compensation line INI may be disposed at the same layer, and the first gate line GL1 may be disposed on an insulating layer covering the second power lines EVSS, the first data line DL1, the second data line DL2 and the compensation line INI. This can be seen by referring to the following description given with reference to FIG. 15, etc.

As shown in FIGS. 14 to 16, each second power line EVSS may be disposed on a substrate SUB. The second power line EVSS may also function as a light shielding layer LSD configured to shield external light incident upon a channel region CHA of the driving transistor DT. To this end, as a material of the second power line EVSS, a material exhibiting an excellent optical blocking ratio may be selected. A buffer layer BUF may be formed on the second power line EVSS, and may expose a portion of the second power line EVSS.

A semiconductor layer ACT may be formed on the buffer layer BUF. As a material of the semiconductor layer ACT, an oxide semiconductor, for example, indium-gallium-zinc oxide (IGZO), may be selected. In the semiconductor layer ACT, portions thereof, except for a portion thereof corresponding to the channel region CHA of the driving transistor DT, may also be metallized (metallized regions). Metal layers MM1, MM2 and MM3 may be formed on the metallized semiconductor layer ACT in order to enhance electrical characteristics (a reduction in line resistance, a reduction in contact resistance, etc.)

A gate insulating layer GI may be formed on the buffer layer BUF, and may expose portions of the metal layers MM1, MM2 and MM3 formed on the metallized semiconductor layer ACT. Gate metal layers GAT1, GAT2 and GAT3 may be formed on the gate insulating layer GI.

The first gate metal layer GAT1 may be electrically connected to the portion of the first metal layer MM1 and the portion of the second metal layer MM2 exposed through the gate insulating layer GI. The second gate metal layer GAT2 may be electrically connected to the portion of the second power line EVSS exposed through the gate insulating layer GI and the buffer layer BUF. The third gate metal layer GAT3 may be connected to the portion of the third metal layer MM3 exposed through the gate insulating layer GI. The first metal layer MM1 may constitute a second electrode of the driving transistor DT, and the third metal layer MM3 may constitute a first electrode of the driving transistor DT.

An interlayer of an insulating material INS, referred to as “interlayer insulating layer,” may be formed on the gate insulating layer GI, and may expose a portion of the third gate metal layer GAT3. The interlayer insulating layer INS may be formed to have a single-layer structure or a multilayer structure. For example, the interlayer insulating layer INS may be formed to have a single-layer structure based on a protective layer or an overcoat layer or a multilayer structure including a protective layer and an overcoat layer.

A pixel electrode layer PXL may be formed on the interlayer insulating layer INS. The pixel electrode layer PXL may be selected as a cathode of the organic light emitting diode OLED, and may be connected to the third gate metal layer GAT3 via a contact hole CH provided at the interlayer insulating layer INS. The pixel electrode layer PXL may be formed to have a single-layer structure or a multilayer structure. For example, the pixel electrode layer PXL may have a single-layer structure based on a transparent oxide or a multilayer structure including a transparent oxide and a metal.

As shown in FIG. 17, in accordance with a first variant of the third example, the third gate metal layer GAT3 may be omitted. In this case, the pixel electrode layer PXL may be connected to the third metal layer MM3 disposed on the first electrode of the driving transistor DT via a contact hole CH provided at the interlayer insulating layer INS. This structure corresponds to a structure in which the pixel electrode layer PXL and the first electrode of the driving transistor DT indirectly contact each other.

As shown in FIG. 18, in accordance with a second variant of the third example, the third metal layer MM3 as well as the third gate metal layer GAT3 may be omitted. In this case, the pixel electrode layer PXL may be directly connected to the metallized semiconductor layer ACT constituting the first electrode of the driving transistor DT via a contact hole CH provided at the interlayer insulating layer INS. This structure corresponds to a structure in which the pixel electrode layer PXL and the first electrode of the driving transistor DT directly contact each other.

Meanwhile, it is noted that, in order to give a description mainly in conjunction with characterized parts of the present disclosure, the interlayer insulating layer INS, etc. disposed on the gate metal layers are omitted from FIG. 15, and a bank layer, an organic material layer, a common electrode layer (an anode), an encapsulation layer, etc., disposed on the pixel electrode layer PXL are omitted from FIGS. 16 to 18.

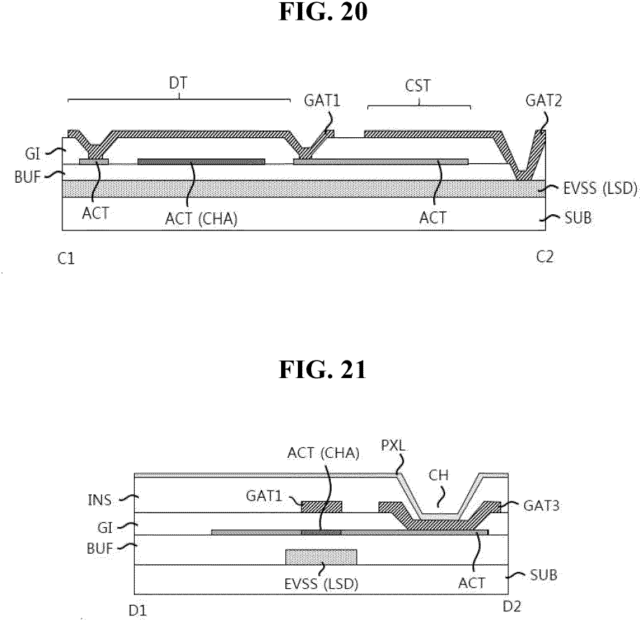

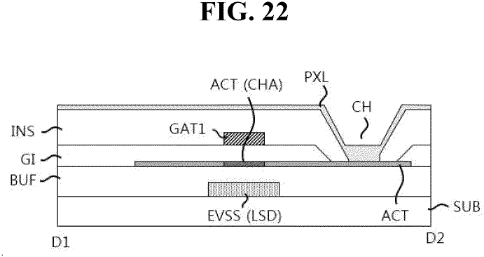

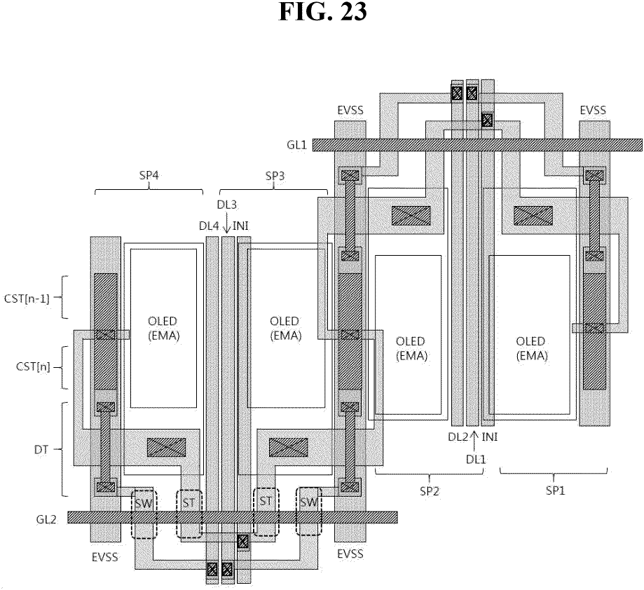

FIG. 19 is an illustrative layout view of subpixels according to a fourth example of the present disclosure. FIG. 20 is an illustrative cross-sectional view taken along line C1-C2 in FIG. 19. FIG. 21 is an illustrative cross-sectional view taken along line D1-D2 in FIG. 19. FIG. 22 is an illustrative cross-sectional view taken along line D1-D2 in FIG. 19, showing a variant of the fourth example of the present disclosure.

As shown in FIG. 19, in accordance with the fourth example of the present disclosure, a first subpixel SP1 and a second subpixel SP2 may each include a switching transistor SW, a driving transistor DT, a compensation transistor ST, a capacitor CST, and an organic light emitting diode OLED. In addition, the capacitor CST and the driving transistor DT may be disposed to extend in a first direction (a vertical direction) of a second power line EVSS in order to overlap with the second power line EVSS.

Identically to the third example, the first subpixel SP1 and the second subpixel SP2 may be disposed to be laterally symmetrical with each other with reference to a first data line DL1, a second data line DL2 and a compensation line INI. In addition, contact structures disposed below a first gate line GL1 may be laterally symmetrical with each other or may be laterally asymmetrical with each other in accordance with a disposition relationship of the first data line DL1, the second data line DL2 and the compensation line INI.

As shown in FIGS. 19 to 21, each second power line EVSS may be disposed on a substrate SUB. The second power line EVSS may also function as a light shielding layer LSD configured to shield external light incident upon a channel region CHA of the driving transistor DT. To this end, as a material of the second power line EVSS, a material exhibiting an excellent optical blocking ratio may be selected. A buffer layer BUF may be formed on the second power line EVSS, and may expose a portion of the second power line EVSS.

A semiconductor layer ACT may be formed on the buffer layer BUF. As a material of the semiconductor layer ACT, an oxide semiconductor, for example, indium-gallium-zinc oxide (IGZO) may be selected. In the semiconductor layer ACT, portions thereof, except for a portion thereof corresponding to the channel region CHA of the driving transistor DT, may also be metallized.

A gate insulating layer GI may be formed on the buffer layer BUF, and may expose the metallized portions of the semiconductor layer ACT. Gate metal layers GAT1, GAT2 and GAT3 may be formed on the gate insulating layer GI. The first gate metal layer GAT1 may be electrically connected to first and second portions of the semiconductor layer ACT exposed through the gate insulating layer GI. The second gate metal layer GAT2 may be connected to the portion of the second power line EVSS exposed through the gate insulating layer GI and the buffer layer BUF. The third gate metal layer GAT3 may be connected to a third portion of the semiconductor layer ACT exposed through the gate insulating layer GI. The first portion of the semiconductor layer ACT may constitute a second electrode of the driving transistor DT, and the third portion of the semiconductor layer ACT may constitute a first electrode of the driving transistor DT.

An interlayer insulating layer INS may be formed on the gate insulating layer GI, and may expose a portion of the third gate metal layer GAT3. The interlayer insulating layer INS may be formed to have a single-layer structure or a multilayer structure. For example, the interlayer insulating layer INS may be formed to have a single-layer structure based on a protective layer or an overcoat layer or a multilayer structure including a protective layer and an overcoat layer.

A pixel electrode layer PXL may be formed on the interlayer insulating layer INS. The pixel electrode layer PXL may be selected as a cathode of the organic light emitting diode OLED, and may be connected to the third gate metal layer GAT3 via a contact hole CH provided at the interlayer insulating layer INS. The pixel electrode layer PXL may be formed to have a single-layer structure or a multilayer structure. For example, the pixel electrode layer PXL may have a single-layer structure based on a transparent oxide or a multilayer structure including a transparent oxide and a metal. Although a bank layer, an organic material layer, a common electrode layer (an anode), an encapsulation layer, etc., may be formed on the pixel electrode layer PXL, no illustration and description thereof are given.

As shown in FIG. 22, in accordance with the variant of the fourth example, the third gate metal layer GAT3 may be omitted. In this case, the pixel electrode layer PXL may be directly connected to the metallized third portion of the semiconductor layer ACT constituting the first electrode of the driving transistor DT via a contact hole CH provided at the interlayer insulating layer INS.

Meanwhile, it is noted that, in order to give a description mainly in conjunction with characterized parts of the present disclosure, the interlayer insulating layer INS, etc., disposed on the gate metal layers are omitted from FIG. 20, and the bank layer, the organic material layer, the common electrode layer (the anode), the encapsulation layer, etc., disposed on the pixel electrode layer PXL are omitted from FIGS. 21 and 22.

FIG. 23 is a circuit diagram of a circuit configuration of a subpixel according to a fifth example of the present disclosure.

As shown in FIG. 23, in accordance with the fifth example of the present disclosure, first to fourth subpixels SP1 to SP4 may each include a switching transistor SW, a driving transistor DT, a compensation transistor ST, a capacitor CST, and an organic light emitting diode OLED. In addition, the capacitor CST and the driving transistor DT may be disposed to extend in a first direction (a vertical direction) of a second power line EVSS in order to overlap with the second power line EVSS.

The first subpixel SP1 and the second subpixel SP2 may be disposed to be laterally symmetrical with each other with reference to a first data line DL1, a second data line DL2 and a compensation line INI corresponding thereto. In addition, the third subpixel SP3 and the fourth subpixel SP4 may be disposed to be laterally symmetrical with each other with reference to a third data line DL3, a fourth data line DL4 and another compensation line INI corresponding thereto.

Contact structures disposed above a first gate line GL1 connected to the first subpixel SP1 and the second subpixel SP2 may be laterally symmetrical with each other or may be laterally asymmetrical with each other in accordance with the disposition relationship of the first data line DL1, the second data line DL2 and the corresponding compensation line INI. In addition, contact structures disposed below a second gate line GL2 connected to the third subpixel SP3 and the fourth subpixel SP4 may be laterally symmetrical with each other or may be laterally asymmetrical with each other in accordance with a disposition relationship of the third data line DL3, the fourth data line DL4 and the corresponding compensation line INI.

In accordance with the fifth example of the present disclosure, the first subpixel SP1 and the second subpixel SP2 may be included in a first group in which subpixels are laterally symmetrical with each other, and the third subpixel SP3 and the fourth subpixel SP4 may be included in a second group in which subpixels are laterally symmetrical with each other. For efficient space utilization, the first group and the second group may be disposed to have vertically inverted relations, respectively.

For example, circuits of the first subpixel SP1 and the second subpixel SP2 included in the first group and the first gate line GL1 may be disposed at a higher position than emission areas EMA of the organic light emitting diodes OLED corresponding thereto. In addition, circuits of the third subpixel SP3 and the fourth subpixel SP4 included in the second group and the second gate line GL2 may be disposed at a lower position than emission areas EMA of the organic light emitting diodes OLED corresponding thereto. Alternatively, a reversed disposition of these elements may be possible.

When the first group and the second group each including two subpixels laterally symmetrical with each other are disposed to be vertically inverted from each other, all of the emission areas EMA of the organic light emitting diodes OLED included in the first to fourth subpixels SP1 to SP4 may be disposed on the same line.

In addition, when the first group and the second group are disposed to be vertically inverted from each other, as described above, an N-1-th capacitor CST[n-1] (e.g., first capacitor) and an N-th capacitor CST[n] (e.g., second capacitor) may overlap with the second power line EVSS corresponding thereto while being adjacent to each other. Here, the N-th capacitor CST[n] may be a capacitor included in the fourth subpixel SP4, and the N-1-th capacitor CST[n-1] may be a capacitor included in a fifth subpixel disposed next to the fourth subpixel SP4. This disposition relationship can be seen by referring to the second subpixel SP2 and the third subpixel SP3 disposed adjacent to each other, but different from each other in terms of vertical disposition.

Meanwhile, although the present disclosure has been described in conjunction with an example in which an organic light emitting diode is connected between a high-level voltage power line and a driving transistor, the present disclosure may also be applied to a structure in which an organic light emitting diode is connected between a driving transistor and a low-level voltage power line. In addition, the present disclosure is applicable to not only a subpixel constituted by two transistors and one capacitor or three transistors and one capacitor, but also to a structure further including a transistor for compensation and a capacitor. Furthermore, although a subpixel has been illustrated and described based on an n-type transistor in the present disclosure, the present disclosure is also applicable to a structure including a p-type transistor or a structure including both an n-type transistor and a p-type transistor.

As apparent from the above description, in accordance with the examples of the present disclosure, there is an effect of achieving an increase in aperture ratio by increasing an area occupied by an organic light emitting diode while minimizing an area required for implementation of a circuit through formation of a capacitor and a driving transistor such that the capacitor and the driving transistor overlap with a low-level voltage power line. In addition, in accordance with the examples of the present disclosure, there is an effect of stabilizing power of a low voltage level and reducing a line resistance through disposition of a low-level voltage power line in each area in which a subpixel is disposed, thereby achieving an enhancement in display quality of the resultant display panel, Furthermore, in accordance with the examples of the present disclosure, there is an effect of compensating a driving transistor without implementation of a separate compensation circuit in a data driver, etc., thereby achieving an enhancement in display quality of the resultant display panel and an increase in lifespan of the display panel.

The foregoing description and the accompanying drawings have been presented in order to illustratively explain technical ideas of the present disclosure. A person skilled in the art to which the present disclosure pertains can appreciate that diverse modifications and variations acquired by combining, dividing, substituting, or changing constituent elements may be possible, without changing essential characteristics of the present disclosure, which remain within the scope of the disclosure. Therefore, the foregoing examples disclosed herein shall be interpreted as illustrative only and not as limitative of the principle and scope of the present disclosure.

Also disclosed herein are a number of examples according to the following numbered clauses.

Clause 1. A light emitting display device comprising:
a low-level voltage power line configured to transmit a low-level voltage;
a data line configured to transmit a data voltage;
a gate line configured to transmit a gate signal, and
a subpixel connected to the low-level voltage power line, the data line and the gate line, the subpixel comprising a capacitor overlapping with the low-level voltage power line.

Clause 2. The light emitting display device according to clause 1, wherein:
the subpixel further comprises a driving transistor having a gate electrode connected to a first electrode of the capacitor; and
the driving transistor overlaps with the low-level voltage power line.

Clause 3. The light emitting display device according to clause 2, wherein:
the first electrode and a second electrode of the capacitor overlaps with the low-level voltage power line; and
the gate electrode and a channel region of the driving transistor overlaps with the low-level voltage power line.

Clause 4. The light emitting display device according to any preceding clause, wherein the subpixel comprises:
the low-level voltage power line disposed on a subpixel;
a buffer layer disposed on the low-level voltage power line;
a semiconductor layer disposed on a buffer layer;
a gate insulating layer disposed on the semiconductor layer;
a gate metal layer disposed on the gate insulating layer;
an interlayer insulating layer disposed on the gate metal layer; and a pixel electrode layer disposed on the interlayer insulating layer.

Clause 5. The light emitting display device according to clause 4, wherein:
the semiconductor layer is selected as an oxide semiconductor comprising a semiconductor region and a metallized region; and
the semiconductor layer further comprises a metal layer disposed in the metallized region.

Clause 6. The light emitting display device according to clause 5, wherein the pixel electrode layer contacts a portion of the metal layer via a contact hole provided at the interlayer insulating layer and the gate insulating layer, thereby being electrically connected to the metallized region.

Clause 7. The light emitting display device according to any of clauses 4 to 6, wherein the pixel electrode layer is directly connected to the metallized region via a contact hole provided at the interlayer insulating layer and the gate insulating layer.

Clause 8. A light emitting display device comprising:
a display panel comprising subpixels each connected to a low-level voltage power line, a data line and a gate line, each of the subpixels comprising a capacitor overlapping with the low-level voltage power line; and
a driver configured to drive the display panel,
wherein the subpixels comprise a first group and a second group each comprising two subpixels laterally symmetrical with each other, and the first group and the second group have vertically inverted relations, respectively.

Clause 9. The light emitting display device according to clause 8, wherein:
a first electrode and a second electrode of the capacitor overlaps with the low-level voltage power line; and
a gate electrode and a channel region of the driving transistor overlaps with the low-level voltage power line.

Clause 10. A manufacturing method of a light emitting display device comprising:
forming, on a substrate, a subpixel connected to a low-level voltage power line, a data line and a gate line while comprising a capacitor overlapping with the low-level voltage power line; and
encapsulating the subpixel formed on the substrate,
wherein the capacitor comprises a first electrode disposed on a buffer layer covering the low-level voltage power line, and a second electrode disposed on a gate insulating layer covering the one-end electrode, and
wherein the first electrode of the capacitor comprises a metallized oxide semiconductor layer.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the abovedetailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display device comprising:
a low-level voltage power line configured to transmit a low-level voltage;
a data line configured to transmit a data voltage;
a gate line configured to transmit a gate signal, and
a subpixel connected to the low-level voltage power line, the data line and the gate line, the subpixel comprising a capacitor overlapping with the low-level voltage power line.

2. The light emitting display device according to claim 1, wherein:
the subpixel further comprises a driving transistor having a gate electrode connected to a first electrode of the capacitor; and
the driving transistor overlaps with the low-level voltage power line.

3. The light emitting display device according to claim 2, wherein:
the first electrode and a second electrode of the capacitor overlap with the low-level voltage power line; and
the gate electrode and a channel region of the driving transistor overlap with the low-level voltage power line.

4. The light emitting display device according to claim 2, wherein:
the subpixel further comprises a switching transistor configured to transmit the data voltage to the gate electrode of the driving transistor and to the first electrode of the capacitor; and
the switching transistor overlaps with the gate line.

5. The light emitting display device according to claim 4, wherein the switching transistor has:
a gate electrode connected to the gate line;
a first electrode connected to the data line; and
a second electrode connected to the gate electrode of the driving transistor and to the first electrode of the capacitor.

6. The light emitting display device of claim 2, wherein:
the low-level voltage power line extends in a first direction in a plane of the light emitting display device; and
the gate line extends in a second direction which crosses the first direction and is parallel to the plane of the light emitting display device.

7. The light emitting display device of claim 6, wherein the capacitor and the driving transistor are arranged along the first direction and each overlaps with the low-level voltage power line.

8. The light emitting display device of claim 6, wherein:
the subpixel further comprises an organic light emitting diode; and
the organic light emitting diode is located between the low-level voltage power line and the data line in plan view.

9. The light emitting display device according to claim 1, wherein the subpixel comprises:
a buffer layer disposed on the low-level voltage power line;
a semiconductor layer disposed on the buffer layer;
a gate insulating layer disposed on the semiconductor layer;
a gate metal layer disposed on the gate insulating layer;
an interlayer of an insulating material disposed on the gate metal layer; and
a pixel electrode layer disposed on the interlayer.

10. The light emitting display device according to claim 9, wherein:
the semiconductor layer is selected as an oxide semiconductor comprising a semiconductor region and a metallized region; and
the semiconductor layer further comprises a metal layer disposed in the metallized region.

11. The light emitting display device according to claim 10, wherein the pixel electrode layer contacts a portion of the metal layer via a contact hole provided at the interlayer and the gate insulating layer, thereby being electrically connected to the metallized region.

12. The light emitting display device according to claim 9, wherein the pixel electrode layer is directly connected to the metallized region via a contact hole provided at the interlayer and the gate insulating layer.

13. The light emitting display device according to claim 8, wherein
the subpixel further comprises a compensation transistor configured to apply a compensation voltage to the organic light emitting diode; and
the compensation transistor overlaps with the gate line.

14. The light emitting display device according to claim 13, wherein the compensation transistor has:
a gate connected to the gate line;
a first electrode connected to a cathode of the organic light emitting diode and a first electrode of the driving transistor; and
a second electrode connected to a compensation line.

15. The light emitting display device of claim 14, wherein the compensation line is adjacent to the data line and extends in the first direction.

16. The light emitting display device according to claim 1, wherein the capacitor comprises a first electrode disposed on a buffer layer covering the low-level voltage power line, and a second electrode disposed on a gate insulating layer covering the first electrode, and
wherein the first electrode of the capacitor comprises a metallized oxide semiconductor layer.

17. The light emitting display device according to claim 1, comprising:
a plurality of subpixels, wherein each subpixel is connected to the low-level voltage power line, the data line and the gate line, and wherein each subpixel comprises a capacitor overlapping with the low-level voltage power line; and
a driver configured to drive the display panel,
wherein the subpixels comprise a first group and a second group, wherein each group comprises two subpixels laterally symmetrical with each other, and wherein the subpixels of the first group are inverted relative to the subpixels of the second group.

18. A light emitting display device comprising:
a display panel comprising subpixels each connected to a low-level voltage power line, a data line and a gate line, each of the subpixels comprising a capacitor overlapping with the low-level voltage power line; and
a driver configured to drive the display panel,
wherein the subpixels comprise a first group and a second group, wherein each group comprises two subpixels laterally symmetrical with each other, and wherein the subpixels of the first group are inverted relative to the subpixels of the second group.

19. The light emitting display device according to claim 18, wherein:
each subpixel comprises a driving transistor having a gate electrode connected to a first electrode of the capacitor;
the first electrode and a second electrode of each capacitor overlap with the low-level voltage power line; and
the gate electrode and a channel region of each driving transistor overlap with the low-level voltage power line.

20. The light emitting display device according to claim 18, wherein a first subpixel includes a first capacitor and a second subpixel includes a second capacitor, each of the first and second capacitors overlapping with the low-level voltage power line corresponding thereto, the first and second subpixels adjacent to each other and the first and second capacitors adjacent to each other.

21. A manufacturing method of a light emitting display device comprising:
forming a subpixel connected to a low-level voltage power line, a data line a capacitor and a gate line; and
encapsulating the subpixel formed on the substrate,
wherein the capacitor has at least one electrode overlapping with the low-level voltage power line.

22. The manufacturing method of claim 21, comprising:
forming a display panel that include a plurality of subpixels including the subpixel; and
forming a driver configured to drive the display panel,
wherein the plurality of subpixels that comprise a first group and a second group, wherein each group comprises two subpixels laterally symmetrical with each other, and wherein the subpixels of the first group are inverted relative to the subpixels of the second group.
